(19) United States
(12) Patent Application Publication
(10) Pub. No.: US 2026/0169386 A1
(43) Pub. Date: Jun. 18, 2026

(54) FILM FORMING METHOD AND FILM FORMING APPARATUS

(71) Applicants: THE UNIVERSITY OF TOKYO, Tokyo (JP); Tokyo Electron Limited, Tokyo (JP)

(72) Inventors: Takao OKABE, Tokyo (JP); Shinichi TANABE, Tokyo (JP); Toshikazu AKIMOTO, Tokyo (JP); Naoki UMESHITA, Tokyo (JP)

(73) Assignees: THE UNIVERSITY OF TOKYO, Tokyo (JP); Tokyo Electron Limited, Tokyo (JP)

(21) Appl. No.: 19/375,211

(22) Filed: Oct. 31, 2025

Related U.S. Application Data
(63) Continuation of application No. PCT/JP2024/016634, filed on Apr. 30, 2024.

(30) Foreign Application Priority Data
May 11, 2023 (JP) 2023-078598

(51) Int. Cl. G03F 7/16; C08J 5/18; G03F 7/028; H10P 76/20

(52) U.S. Cl. CPC G03F 7/162; C08J 5/18; G03F 7/028; G03F 7/168; C08J 2333/08; H10P 76/2041

(57) ABSTRACT

A film forming method includes step a), step b), and step c). The step a) is structured to apply, on a substrate, a solution of a film forming material to be formed into a film, dissolved in a first ionic liquid capable of dissolving the film forming material. The step b) is structured to apply a second ionic liquid incapable of dissolving the film forming material but miscible with the first ionic liquid. The step c) is structured to remove the second ionic liquid having been mixed with the first ionic liquid, from the substrate.

### CROSS-REFERENCE TO RELATED APPLICATIONS

This application is a continuation of International Application No. PCT/JP2024/016634, filed on Apr. 30, 2024 which claims the benefit of priority of the prior Japanese Patent Application No. 2023-078598, filed on May 11, 2023, the entire contents of each are incorporated herein by reference.

### FIELD

The present disclosure relates to a film forming method and a film forming apparatus.

### BACKGROUND

Japanese Laid-open Patent Publication No. 2011-108731 discloses “a photoresist coater/developer for forming a photoresist film on a substrate, and for developing the photoresist film after exposure, the photoresist coater/developer comprises: a photoresist film forming unit structured to form a photoresist film on the substrate; a heat treatment unit structured to heat the substrate having the photoresist film formed thereon, in the photoresist film forming unit; a cooling unit structured to cool the substrate having the photoresist film formed thereon, heated in the heat treatment unit, down to normal temperature; a heating unit structured to heat the substrate, cooled down to the normal temperature in the cooling unit, up to a predetermined temperature; a load-lock chamber structured to unload, under reduced pressure, the substrate directed to exposure of the photoresist film; and a transfer section structured to transfer the substrate from the heating unit to the load-lock chamber”.

The present disclosure provides a technique capable of stably forming a film by coating.

### SUMMARY

According to an aspect of a present disclosure, a film forming method includes: a) applying, on a substrate, a solution of a film forming material to be formed into a film, dissolved in a first ionic liquid capable of dissolving the film forming material; b) applying, on the substrate, a second ionic liquid incapable of dissolving the film forming material but miscible with the first ionic liquid; and c) removing the second ionic liquid having been mixed with the first ionic liquid, from the substrate.

### BRIEF DESCRIPTION OF DRAWINGS

FIG. 1 is a diagram illustrating an exemplary flow of a film forming method according to an embodiment;

FIGS. 2(A) to 2(E) are diagrams schematically illustrating exemplary changes on a substrate during film formation by the film forming method according to the embodiment;

FIG. 3 is a block diagram schematically illustrating an exemplary structure of a film forming apparatus according to the embodiment; and

FIG. 4 is a diagram schematically illustrating a part of a manufacturing process of a semiconductor device.

### DESCRIPTION OF EMBODIMENTS

Hereinafter, exemplary embodiments of a film forming method and a film forming apparatus disclosed in the present application will be detailed, with reference to the attached drawings. Note the film forming method and the film forming apparatus disclosed herein are not limited to the embodiment.

Some film forming apparatuses, such as spin coater, have been known to form a film such as a photoresist film on a substrate. This sort of film forming apparatus is structured to apply a film forming material while being dissolved in a solvent, to a substrate, and to pre-bake the substrate so as to allow only the solvent to evaporate, thereby leaving the film made of the film forming material on the substrate. The substrate under pre-baking will, however, temporarily undergo thermal expansion, and will then shrink as the temperature thereof lowers thereafter. Exposure of the photoresist in such situation would cause misalignment of patterns.

### EMBODIMENT

### Ionic Liquid

An embodiment will be described. Hereinafter, an exemplary case where a photoresist film is formed on a substrate such as a semiconductor wafer will be described. The film forming method according to the embodiment is directed to form a photoresist film on a substrate, with use of an ionic liquid. The ionic liquid is an ionic compound that stays liquid at normal temperature, and is also referred to as ambient temperature molten salt. The ionic liquid is featured by a vapor pressure of almost zero, and non-volatility (will not volatilize both at high temperatures and under vacuum). The ionic liquid is composed of a cation and an anion.

The cation that constitutes the ionic liquid is exemplified by nitrogen-containing ones of pyridinium type, imidazolium type, ammonium type, pyrrolidinium type, and piperidinium type; and phosphorus-containing ones of phosphonium type. Each of these cations typically has an alkyl group —(CH₂)ₙCH₃ in the side chain. Other examples of the cation that constitutes the ionic liquid include those of morphonium type, and sulfonium type.

The pyridinium type cation is exemplified by, but not limited to, C₂py⁺ represented by chemical formula (C1-1), and C₄py⁺ represented by chemical formula (C1-2).

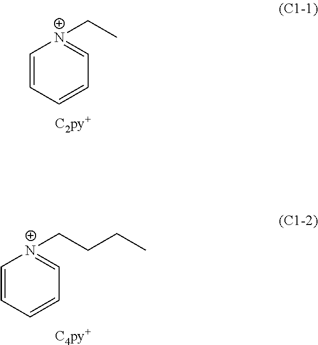

The imidazolium type cation is exemplified by, but not limited to, C₂mim⁺ represented by chemical formula (C2-1), C₄mim⁺ represented by chemical formula (C2-2), C₆mim⁺ represented by chemical formula (C2-3), and C₈mim⁺ represented by chemical formula (C2-4).

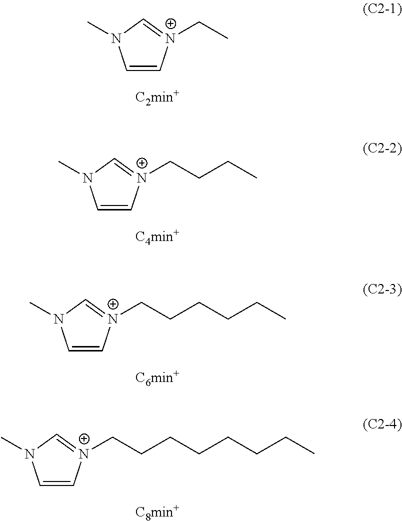

The ammonium type cation is exemplified by, but not limited to, N_{3,1,1,1}⁺ represented by chemical formula (C3-1), N_{4,1,1,1}⁺ represented by chemical formula (C3-2), N_{6,1,1,1}⁺ represented by chemical formula (C3-3), and N_{2,2,1,(201)}⁺ represented by chemical formula (C3-4), and Ch⁺ represented by chemical formula (C3-5).

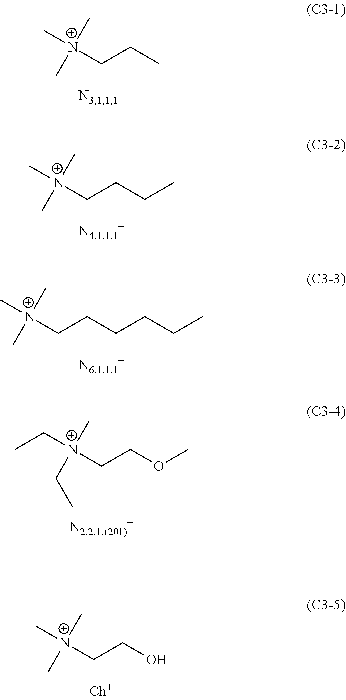

The pyrrolidinium type cation is exemplified by, but not limited to, Pyr_{1,3}⁺ represented by chemical formula (C4-1), and Pyr_{1,4}⁺ represented by chemical formula (C4-2).

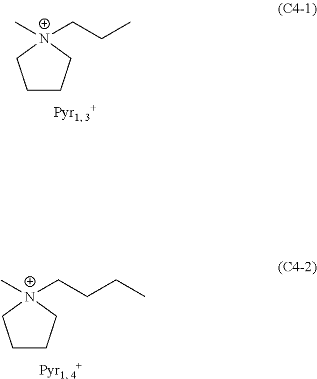

The piperidinium type cation is exemplified by, but not limited to, Pip_{1,3}⁺ represented by chemical formula (C5-1), and Pip_{1,4}⁺ represented by chemical formula (C5-2).

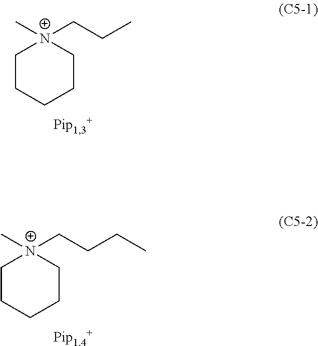

The phosphonium type cation is exemplified by, but not limited to, P_{5,2,2,2}⁺ represented by chemical formula (C6-1), and P_{6,6,6,14}⁺ represented by chemical formula (C6-2).

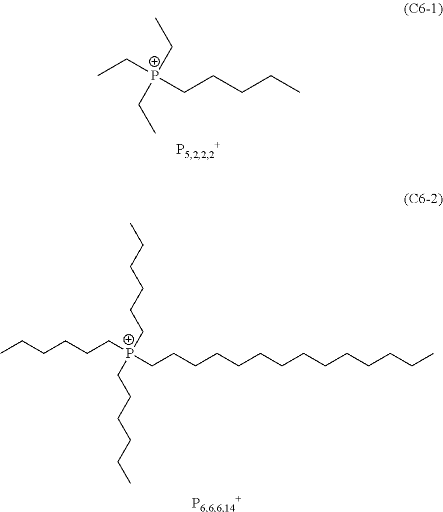 [SMILES: CCCCC[P+](CC)(CC)CC ; CCCCCCCCCCCCCC[P+](CCCCCC)(CCCCCC)CCCCCC]

The anion that constitutes the ionic liquid is exemplified by TfO⁻ represented by chemical formula (A1), Tf₂N⁻ (TFSA⁻) represented by chemical formula (A2), Tf₃C⁻ represented by the chemical formula (A3), FSA-represented by chemical formula (A4), CH₃COO⁻ represented by chemical formula (A5), CF₃COO⁻ represented by chemical formula (A6), BF₄⁻ represented by chemical formula (A7), PF₆⁻ represented by chemical formula (A8), (CN)₂N⁻ represented by chemical formula (A9), AlCl₄⁻ represented by chemical formula (A10), and Al₂Cl₇⁻ represented by chemical formula (A11). Other examples of the anion that constitutes the ionic liquid include PF₆⁻ and Cl⁻.

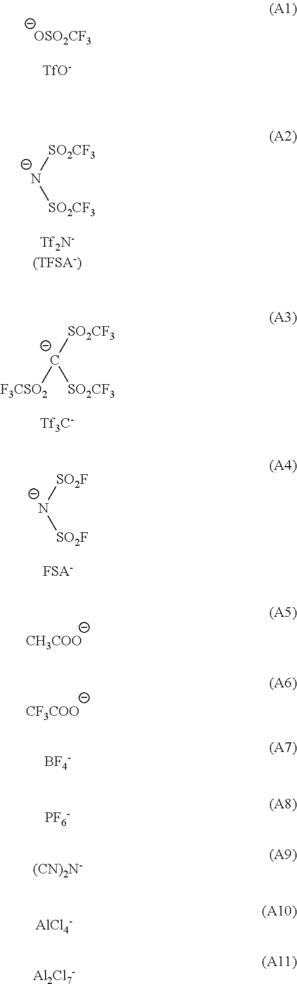

Specific examples of the ionic liquid include N,N-diethyl-N-methyl-N-(2-methoxyethyl)ammonium bis(trifluoromethanesulfonyl)imide (DEME·TFSA), and 1-ethyl-3-methylimidazolium dicyanamide.

The ionic liquid will have materials dissolvable therein, which vary depending on combination of the cation and the anion.

In the film forming method according to the embodiment, the film is formed with use of the film forming material, the first ionic liquid, and the second ionic liquid. The film forming material used herein is soluble in the first ionic liquid, and insoluble in the second ionic liquid. The first ionic liquid used herein is more miscible with the second ionic liquid, than with the film forming material.

In this embodiment, a photoresist film is formed on the substrate. The film forming material is selectable from the previously known resist materials which are soluble in the first ionic liquid, and insoluble in the second ionic liquid. The previously known photoresist film is exemplified by chemically amplified resist, and non-chemically amplified resist. The chemically amplified resist is based on combination of a photosensitizer (“t-BOC” functional group, for example) that induces acid generation, with a monomer or polymer. The non-chemically amplified resist is based on combination of a photosensitizer, with a monomer or polymer (polymethyl methacrylate (PMMA), for example) that acts as a non-chemically amplified resist. The first ionic liquid used herein is more miscible with the second ionic liquid, than with the resist material.

### Film Forming Method

Next, a film forming method according to the embodiment will be described. In the film forming method according to the embodiment, the solution of the resist material dissolved in a first ionic liquid, and the second ionic liquid are prepared for film formation. The resist material used herein is a resin in the form of monomer, which is polymerized by light of a predetermined wavelength to be converted into a polymer. The solution may further have a photopolymerization initiator dissolved therein. The photopolymerization initiator is selected from the previously known ones, especially from those soluble in the first ionic liquid, and adapted to polymerization of the monomer material.

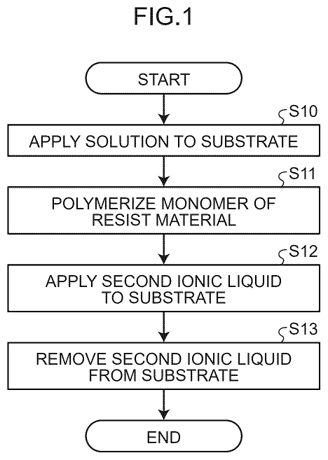

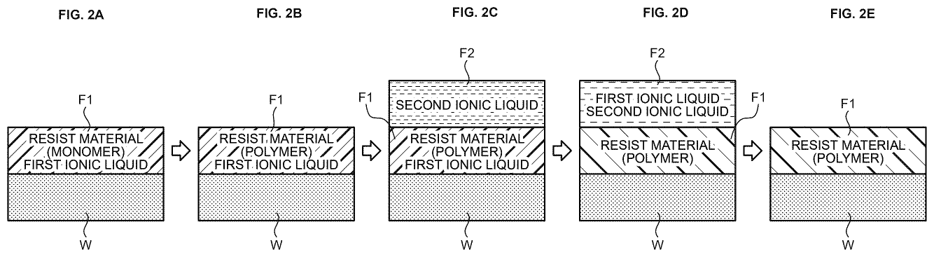

FIG. 1 is a diagram illustrating an exemplary flow of the film forming method according to the embodiment. FIGS. 2(A) to 2(E) are diagrams schematically illustrating exemplary changes on a substrate W during film formation by the film forming method according to the embodiment.

In step S10, a solution of the resist material dissolved in the first ionic liquid is applied to the substrate W (step S10). A film F1 of the solution is thus formed on the substrate W, as illustrated in FIG. 2(A). The film F1 contains a monomer resin of the resist material, and the first ionic liquid.

In step S11, the substrate W is irradiated with light of a predetermined wavelength. The resist material contained in the film F1 is thus converted to a polymer, as illustrated in FIG. 2(B). Note that step S11 is omissible, if the resist material used in step S10 is a polymer resin.

In step S12, the second ionic liquid is applied to the substrate W. A film F2 formed of the second ionic liquid is thus formed on the film F1, as illustrated in FIG. 2(C). The polymer resin ascribed to the resist material contained in the film F1 is insoluble in the second ionic liquid that forms the film F2, and therefore remains in the film F1. On the other hand, the first ionic liquid contained in the film F1 is miscible with the second ionic liquid that forms the film F2. This causes solvent substitution, leaving the polymer resin ascribed to the resist material in the film F1, as illustrated in FIG. 2(D).

In step S13, the second ionic liquid having been mixed with the first ionic liquid is removed from the substrate W. The film F1 formed of the resin ascribed to the resist material thus remains on the substrate W, as illustrated in FIG. 2(E).

In this way, the film forming method according to the embodiment can stably form, by coating, the film F1 of the resist material on the substrate W. Moreover, the film forming method according to the embodiment, which involves film formation with use of the ionic liquid, can form the film F1 not only in an atmospheric pressure environment at atmospheric pressure, but also in a vacuum environment.

In the film forming method according to the embodiment when aimed at forming a double-layered resist structure, a resist material which is sensitive to wavelength different from that for the film F1 may be additionally used, thereby forming the film F2 sensitive to light of the different wavelength on the surface of the film F1, by repeating step S10 to step S13.

### Structure of Film Forming Apparatus 10

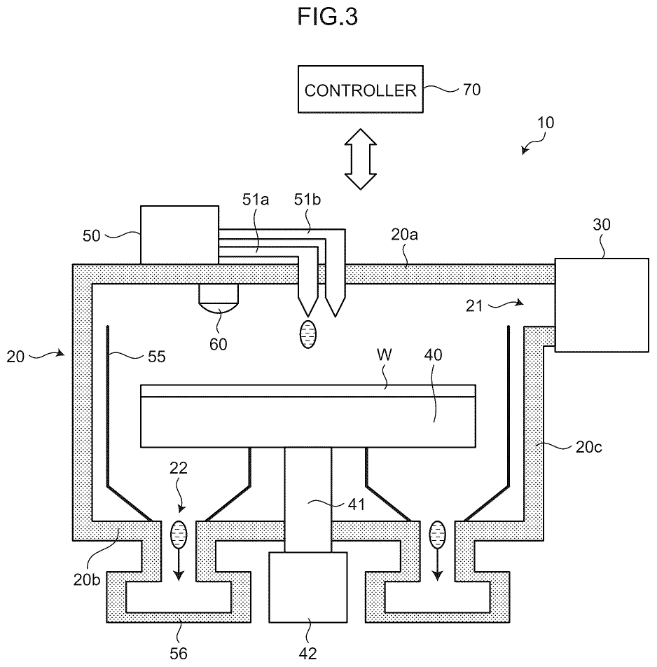

Next, an example of a film forming apparatus 10 for implementing the film forming method according to the embodiment will be described. FIG. 3 is a block diagram schematically illustrating an exemplary structure of the film forming apparatus 10 according to the embodiment. The film forming apparatus 10 has a chamber 20, an exhaust mechanism 30, a stage 40, a supply unit 50, a light source 60, and a controller 70.

The chamber 20 is structured to have the inside kept airtight. The chamber 20 has a top wall 20a and a bottom wall 20b, and a side wall 20c that connects these walls.

In the side wall 20c of the chamber 20, an exhaust port 21 is formed. To the chamber 20, an exhaust mechanism 30 is connected through the exhaust port 21. The exhaust mechanism 30 is provided with a vacuum pump and a pressure control valve. The exhaust mechanism 30 is structured to adjust the pressure inside the chamber 20, by controlling the vacuum pump and the pressure control valve. The vacuum pump usable herein is exemplified by dry pump and turbo molecular pump. The chamber 20 may not only be structured to be pressure-adjustable as described above, but may also have an inert atmosphere at atmospheric pressure, while being supplied with N₂ or the like through an unillustrated gas port.

Substantially at the center of the chamber 20, a stage 40 is disposed. The stage 40 is formed in a disk shape. The stage 40 is allowed for placement of the substrate W on the upper surface. The stage 40 holds the substrate W, typically with the aid of electrostatic chuck, mechanical chuck, or surface tension of the ionic liquid.

The stage 40 is supported by a support member 41, at a central portion of the lower surface. Outside the bottom wall 20b of the chamber 20, a rotary drive mechanism 42 is provided. The support member 41 is extended through the bottom wall 20b of the chamber 20, to be connected to the rotary drive mechanism 42. The rotary drive mechanism 42 rotatably supports the support member 41. The stage 40 is rotatably supported by the support member 41 and the rotary drive mechanism 42. The rotary drive mechanism 42 has a built-in motor, and rotates the support member 41 with use of the driving force of the motor, thereby rotating the stage 40. The stage 40 rotates in the circumferential direction about a center axis of disk which is assumed as the axis of rotation. The stage 40 also has a built-in heater, and is structured to adjust temperature of the substrate W through heating with the heater.

Outside the top wall 20a of the chamber 20, the supply unit 50 is disposed. To the supply unit 50, pipes 51a and 51b that extend through the top wall 20a of the chamber 20 are connected. The pipes 51a and 51b are arranged so as to locate the ends thereof above the stage 40. The supply unit 50 is provided with tanks that individually store various liquids used for the film formation, a pump, a vacuum deaerator, and the like. The supply unit 50 supplies various liquids used for the film formation, individually through the pipes 51a and 51b. In an exemplary case where a photoresist film is formed on the substrate W, the supply unit 50 is provided with a tank that stores the solution of the resist material dissolved in the first ionic liquid, and a tank that stores the second ionic liquid. The supply unit 50 supplies the solution and the second ionic liquid to the chamber 20 whose inside is kept in vacuum atmosphere, while applying mechanical pressure. The supply unit 50 supplies the solution through the pipe 51a, and the second ionic liquid through the pipe 51b. Inside the chamber 20, the solution and the second ionic liquid are dropped from the ends of the pipes 51a and 51b, respectively, to be supplied onto the substrate W held on the stage 40. The film forming apparatus 10 causes spin-coating, by supplying the liquids from the supply unit 50 onto the substrate W, while rotating the stage 40. Note, the supply unit 50 may alternatively be structured to supply the individual liquids, through the pipes 51a and 51b each having a slit coater provided to the leading end thereof.

In the circumference of the stage 40, there is provided a recovery cup 55 for recovering the liquids. The recovery cup 55 may have the upper end thereof inclined towards the stage 40, so as to suppress splashing of the liquids. In the bottom wall 20b of the chamber 20, a plurality of recovery ports 22 are formed so as to surround the rotary drive mechanism 42. The recovery cup 55 is formed like a funnel with the bottom shrunk downwards, and is connected to the recovery ports 22. The recovery ports 22 are connected to a recovery tank 56. The liquids recovered by the recovery cup 55 are stored in the recovery tank 56 with the aid of gravity.

Above the stage 40, a light source 60 is disposed. The light source 60 irradiates the substrate W with light of a predetermined wavelength at which the monomer of the resist material is converted into a polymer.

The controller 70 has a memory, a processor, and an input/output interface. The memory stores a program run on a processor, and a recipe that contains conditions for the individual processes. The processor runs the program read from the memory, so as to control the individual units of the film forming apparatus 10 via the input/output interface, according to the recipe stored in the memory.

Next, operations of the film forming apparatus 10 will be briefly described.

The substrate W subject to film formation is loaded by a transfer mechanism such as a transfer arm, through an unillustrated load/unload port into the chamber 20, and is placed on the stage 40.

Prior to the formation of the photoresist film, the controller 70 controls the exhaust mechanism 30 to exhaust the inside of the chamber 20 down to a predetermined degree of vacuum.

The film forming apparatus 10 applies the solution of the resist material dissolved in the first ionic liquid, onto the substrate W. For example, the controller 70 controls the rotary drive mechanism 42 to rotate the stage 40. Rotational speed of the stage 40 is determined in advance typically by experiment, so as to be adaptable to the spin-coating. The controller 70 controls the supply unit 50 to supply the solution from the supply unit 50 through the pipe 51a, while rotating the stage 40, and drops the solution onto the substrate W on the stage 40, thus causing spin-coating of the solution on the substrate W.

Next, the film forming apparatus 10 irradiates the substrate W with light of a predetermined wavelength, thereby converting the monomer of the resist material into a polymer. For example, the controller 70 controls the light source 60, while rotating the stage 40, so as to allow the light source 60 to irradiate the substrate W with light of a predetermined wavelength, thereby converting the monomer of the resist material contained in the spin-coated film into a polymer.

Next, the film forming apparatus 10 applies the second ionic liquid onto the substrate W. For example, the controller 70 controls the supply unit 50, while rotating the stage 40, so as to allow the supply unit 50 to supply the second ionic liquid through the pipe 51b, and to drop the second ionic liquid onto the substrate W on the stage 40, thus causing spin-coating of the second ionic liquid on the substrate W.

Next, the film forming apparatus 10 waits for solvent substitution. For example, the controller 70 controls the rotary drive mechanism 42 to stop rotation of the stage 40, and maintain the stage 40 as it is for a predetermined length of time. The predetermined length of time herein means the length of time up to completion of the solvent substitution, having been determined in advance typically by experiment.

Next, the film forming apparatus 10 removes the second ionic liquid from the substrate W. For example, the controller 70 controls the rotary drive mechanism 42 to rotate the stage 40 faster than during the spin-coating of the solution and the second ionic liquid, thereby removing the second ionic liquid from the substrate W by spin-drying. Rotational speed of the stage 40 is determined in advance typically by experiment, so as to be adaptable to the spin-drying. Note the viscosity of the ionic liquids tends to decrease as the temperature rises. The controller 70 may therefore conduct the spin-drying under rotation of the stage 40, while causing a heater embedded in the stage 40 to generate heat so as to warm the substrate W, and to lower the viscosity of the first ionic liquid and second ionic liquid having been spin-coated thereon. The substrate W herein is warmed only up to a temperature which will be non-problematic for the substrate W, since large thermal expansion of the substrate W will cause misalignment of patterns in the subsequent light exposure.

### Exemplary Film Formation

Next, an exemplary film formation with the resist material on the substrate W will be described.

The substrate W used herein was a silicon substrate. The resist material used herein was a mixture of 1,6-hexanediol diacrylate (HDDA) and an oligomer. The oligomer used herein was trade name: epoxy ester 70PA (chemical name: Epolite 70P acrylic acid adduct) from Kyoeisha Chemical Co., Ltd. The first ionic liquid used herein contains N,N-diethyl-N-methyl-N-(2-methoxyethyl)ammonium (DEME) as the cation, and bis(trifluoromethanesulfonyl)imide (TFSA⁻) as the anion. To the solution of the resist material dissolved in the first ionic liquid, further dissolved was a photopolymerization initiator. The photopolymerization initiator used herein was Omnirad 369 from IGM Resins. The second ionic liquid used herein contains 1-ethyl-3-methylimidazolium (EMIM) as the a cation, and dicyanamide (DCA⁻) as the anion.

A film was formed on a silicon substrate, following the flow of the film forming method according to the embodiment illustrated in FIG. 1. In step S11, UV light was irradiated to convert the monomer of the resist material into a polymer. As a result of the film formation by the film formation method according to the embodiment, the resist material was stably applied and formed into a film on the silicon substrate.

Incidentally, films such as the resist material and oxidation protective film have been formed by spin-coating. The previous film formation has been implemented typically by spin-coating the polymer dissolved in a solvent, and then pre-baking the substrate W so as to vaporize only the solvent, thereby leaving the film of the polymer on the substrate W. The previous film formation, which employs highly volatile solvent, would fail in uniform film formation if implemented in vacuum, due to boiling or unintended volatilization. Moreover, the vacuum would not be maintained due to diffusion of gas ascribed to the vaporized solvent. The prior film formation has therefore been implemented in the atmosphere, or in an inert gas conditioned equally to the atmospheric pressure. The prior film formation has, however, been implemented with use of the solution or an atmosphere that contains atmospheric moisture or oxygen, so that the film thus formed would contain bubbles generated therein, or the surface of the substrate W would be unintentionally oxidized.

In contrast, the film forming method according to the embodiment employs the ionic liquids for the film formation as described above, and can form the film not only in an atmospheric pressure environment at the atmospheric pressure, but also in a vacuum environment with reduced pressure. The film forming method according to the embodiment, which involves film formation under vacuum environment, can suppress generation of bubbles in the film to be formed, and unintended oxidation of the surface of the substrate W.

Recent advancing shrinkage of semiconductor devices has promoted employment of an extreme ultraviolet exposure apparatus that uses extreme ultraviolet light (referred to as EUV light, hereinafter) as an exposure light. The exposure of EUV light, which cannot transmit through the air, is necessarily implemented in vacuum. If the resist film is desired to be formed in the air as previously, a load-lock mechanism as an interface is indispensable between the film forming apparatus and the EUV exposure apparatus.

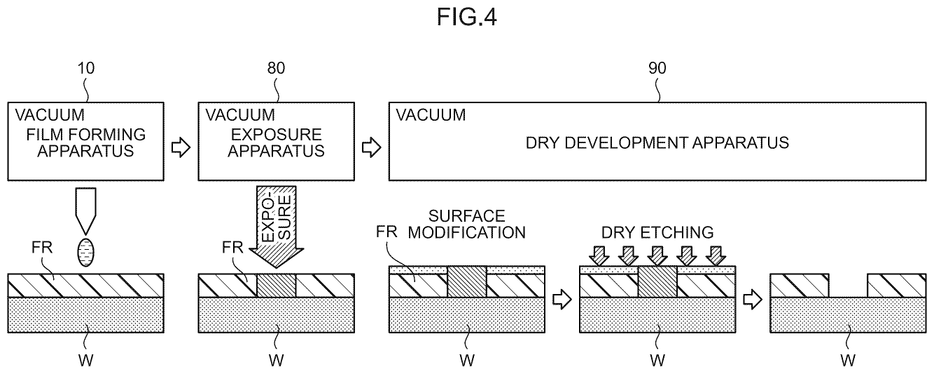

The film forming method according to the embodiment involves film formation in a vacuum environment, thus making it possible to omit transfer of the substrate W between an atmospheric pressure environment and the vacuum environment, when forming the resist film in the manufacturing process. FIG. 4 is a diagram schematically illustrating a part of a manufacturing process of a semiconductor device. As seen in FIG. 4, a resist film FR is formed on the substrate W in a vacuum environment, with use of the film forming apparatus 10 of this embodiment. Next, the resist film FR formed on the substrate W is exposed to light, in a vacuum environment with use of an exposure apparatus 80. This is followed by development, which has previously been conducted under atmospheric pressure, with use of a dry development apparatus 90 in the vacuum environment. In Example, surface modification and dry etching of the substrate W take place. The dry development apparatus 90 used herein may typically be a plasma processing apparatus allowed for plasma treatment such as plasma etching.

The film forming method according to the embodiment, which involves film formation in a vacuum environment, can use any compound despite its sensitivity to oxygen or moisture, without allowing the compound to react with oxygen or moisture. Hence, even an oxygen- or moisture-sensitive material, whose use has been avoided under atmospheric pressure, will now become selectable as the EUV resist material.

The film forming method according to the embodiment, which involves use of the ionic liquid, can form the film without relying upon heating or evaporation even in a vacuum environment. Note for example for the film formation by evaporation, a material used for evaporation necessarily has heat resistance enough to prevent decomposition under heating of an evaporation source. In addition, materials having low vapor pressure are less likely to evaporate. The materials having low vapor pressure are therefore difficult to use. In addition, composite materials composed of a plurality of materials are difficult to be adjusted to desired compositions, due to difference in vapor pressure or evaporation rate of the individual materials.

In contrast, the film forming method according to the embodiment can use any low heat resistant compounds likely to be decomposed under heating, materials having low vapor pressure, or composite materials. As described above, the film forming method according to the embodiment, which involves use of the ionic liquid, can use the materials having been difficult to use before. That is, the film forming method according to the embodiment can expand options of materials to be used.

For example as seen in FIG. 4, connection of the film forming apparatus 10, the exposure apparatus 80, and the dry development apparatus 90 with use of vacuum transfer devices capable of transferring the substrate W under vacuum, enables transfer of the substrate W in a vacuum environment, thereby implementing a manufacturing process of semiconductor devices. With such structure, a series of manufacturing processes including film formation, exposure, and development of the resist film can be implemented overall in a vacuum environment.

The embodiment above has described an exemplary case where the photoresist film is formed on the substrate W by the film forming method. The embodiment is, however, not limited thereto. The film formed by the film forming method may be of any type. For example, an oxidation protective film may be formed on the substrate W by the film forming method. The film forming material in this case is selectable from the previously known oxidation protective film materials which are soluble in the first ionic liquid, and insoluble in the second ionic liquid.

The embodiment above has described an exemplary case where the substrate W is a semiconductor wafer. The embodiment is, however, not limited thereto. The substrate W may alternatively be a glass substrate for flat panel display, or a mask for patterning, for example.

Supplementary notes below will be disclosed with regard to the aforementioned embodiment.

The present disclosure enables stable formation of a film by coating.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

In connection with the above embodiment, the following notes are further disclosed.

### (Note 1)

A film forming method comprising:
a) applying, on a substrate, a solution of a film forming material to be formed into a film, dissolved in a first ionic liquid capable of dissolving the film forming material;
b) applying, on the substrate, a second ionic liquid incapable of dissolving the film forming material but miscible with the first ionic liquid; and
c) removing the second ionic liquid having been mixed with the first ionic liquid, from the substrate.

### (Note 2)

The film forming method according to note 1, wherein
the substrate is disposed in a chamber with the inside depressurized, and
the steps a) to c) are implemented in the chamber.

### (Note 3)

The film forming method according to note 1 or 2, wherein
the film forming material is a resist material or an oxidation protective film material.

### (Note 4)

The film forming method according to any one of notes 1 to 3, wherein
the film forming material is a monomer material that combines to be converted into a polymer under light of a predetermined wavelength, and the film forming method further comprises:
d) irradiating the light of a predetermined wavelength on the substrate so as to convert the film forming material, having been applied on the substrate, into the polymer, the step d) comes between the step a) and the step b).

### (Note 5)

The film forming method according to note 4, wherein
the film forming material is a mixture of 1,6-hexanediol diacrylate (HDDA) and an oligomer,
the first ionic liquid contains N,N-diethyl-N-methyl-N-(2-methoxyethyl)ammonium (DEME) as a cation, and bis(trifluoromethanesulfonyl)imide (TFSA⁻) as an anion, and
the second ionic liquid contains 1-ethyl-3-methylimidazolium (EMIM) as a cation, and dicyanamide (DCA⁻) as an anion.

### (Note 6)

The film forming method according to claim 4 or 5, wherein
the solution further contains a photopolymerization initiator that is soluble in the first ionic liquid, and adapted to polymerization of the monomer material.

### (Note 7)

The film forming method according to any one of notes 1 to 6, wherein
the substrate is held on a rotatable stage,
the step a) is structured to cause spin-coating of the solution on the substrate, by supplying the solution dropwise onto the substrate from above the stage which is kept rotated,
the step b) is structured to cause spin-coating of the second ionic liquid, by supplying the second ionic liquid dropwise onto the substrate from above the stage which is kept rotated, and
the step c) is structured to rotate the stage faster than in the step a) and in the step b), to remove the second ionic liquid having been mixed with the first ionic liquid from the substrate.

### (Note 8)

The film forming method according to note 7, wherein
the stage has a heater embedded therein, and
the step c) is structured to remove the second ionic liquid having been mixed with the first ionic liquid from the substrate, by rotating the stage while causing the heater to generate heat, thereby reducing viscosity of the first ionic liquid and the second ionic liquid having been spin-coated on the substrate.

### (Note 9)

A film forming apparatus comprising:
a supply unit structured to supply, to a substrate held on a stage, a solution of a film forming material to be formed into a film, dissolved in a first ionic liquid capable of dissolving the film forming material, or, a second ionic liquid incapable of dissolving the film forming material but miscible with the first ionic liquid; and
a controller structured to control supply of the second ionic liquid after supplying the solution from the supply unit, and removal of the second ionic liquid having been mixed with the first ionic liquid from the substrate.

### (Note 10)

The film forming apparatus according to note 9, wherein
the stage is disposed in a decompressed chamber, and
the supply unit is structured to supply the solution or the second ionic liquid, by applying mechanical pressure.

### (Note 11)

The film forming apparatus according to note 9 or 10, wherein
the stage is structured to be rotatable, and
the controller is structured to control, while rotating the stage, supply of the second ionic liquid after supplying the solution from the supply unit, and removal of the second ionic liquid having been mixed with the first ionic liquid from the substrate, by increasing rotational speed of the stage.

What is claimed is:

1. A film forming method comprising:
a) applying, on a substrate, a solution of a film forming material to be formed into a film, dissolved in a first ionic liquid capable of dissolving the film forming material;
b) applying, on the substrate, a second ionic liquid incapable of dissolving the film forming material but miscible with the first ionic liquid; and
c) removing the second ionic liquid having been mixed with the first ionic liquid, from the substrate.

2. The film forming method according to claim 1, wherein
the substrate is disposed in a chamber with the inside depressurized, and
the steps a) to c) are implemented in the chamber.

3. The film forming method according to claim 1, wherein
the film forming material is a resist material or an oxidation protective film material.

4. The film forming method according to claim 1, wherein
the film forming material is a monomer material that combines to be converted into a polymer under light of a predetermined wavelength, and the film forming method further comprises:
d) irradiating the light of a predetermined wavelength on the substrate so as to convert the film forming material, having been applied on the substrate, into the polymer, the step d) comes between the step a) and the step b).

5. The film forming method according to claim 4, wherein
the film forming material is a mixture of 1,6-hexanediol diacrylate (HDDA) and an oligomer,
the first ionic liquid contains N,N-diethyl-N-methyl-N-(2-methoxyethyl)ammonium (DEME) as a cation, and bis(trifluoromethanesulfonyl)imide (TFSA⁻) as an anion, and
the second ionic liquid contains 1-ethyl-3-methylimidazolium (EMIM) as a cation, and dicyanamide (DCA⁻) as an anion.

6. The film forming method according to claim 4, wherein
the solution further contains a photopolymerization initiator that is soluble in the first ionic liquid, and adapted to polymerization of the monomer material.

7. The film forming method according to claim 1, wherein
the substrate is held on a rotatable stage,
the step a) is structured to cause spin-coating of the solution on the substrate, by supplying the solution dropwise onto the substrate from above the stage which is kept rotated,
the step b) is structured to cause spin-coating of the second ionic liquid, by supplying the second ionic liquid dropwise onto the substrate from above the stage which is kept rotated, and
the step c) is structured to rotate the stage faster than in the step a) and in the step b), to remove the second ionic liquid having been mixed with the first ionic liquid from the substrate.

8. The film forming method according to claim 7, wherein
the stage has a heater embedded therein, and
the step c) is structured to remove the second ionic liquid having been mixed with the first ionic liquid from the substrate, by rotating the stage while causing the heater to generate heat, thereby reducing viscosity of the first ionic liquid and the second ionic liquid having been spin-coated on the substrate.

9. A film forming apparatus comprising:
a supply unit structured to supply, to a substrate held on a stage, a solution of a film forming material to be formed into a film, dissolved in a first ionic liquid capable of dissolving the film forming material, or, a second ionic liquid incapable of dissolving the film forming material but miscible with the first ionic liquid; and
a controller structured to control supply of the second ionic liquid after supplying the solution from the supply unit, and removal of the second ionic liquid having been mixed with the first ionic liquid from the substrate.

10. The film forming apparatus according to claim 9, wherein
the stage is disposed in a decompressed chamber, and
the supply unit is structured to supply the solution or the second ionic liquid, by applying mechanical pressure.

11. The film forming apparatus according to claim 9, wherein
the stage is structured to be rotatable, and
the controller is structured to control, while rotating the stage, supply of the second ionic liquid after supplying the solution from the supply unit, and removal of the second ionic liquid having been mixed with the first ionic liquid from the substrate, by increasing rotational speed of the stage.
